(19) United States
(12) Patent Application Publication
(10) Pub. No.: US 2008/0283850 A1
(43) Pub. Date: Nov. 20, 2008

(54) Reflective Positive Electrode and Gallium Nitride-Based Compound Semiconductor Light-Emitting Device Using the Same

(76) Inventor: Koji Kamei, Chiba (JP)

Correspondence Address: SUGHRUE MION, PLLC, 2100 PENNSYLVANIA AVENUE, N.W., SUITE 800, WASHINGTON, DC, 20037, US

(21) Appl. No.: 11/629,306

(22) PCT Filed: Jun. 22, 2005
(86) PCT No.: PCT/JP05/11870

§ 371 Date: Dec. 13, 2006

Related U.S. Application Data
(60) Provisional application No. 60/584,175, filed on Jul. 1, 2004.

(30) Foreign Application Priority Data
Jun. 24, 2004 (JP) 2004-186871

(51) Int. Cl. H01L 33/00

(52) U.S. Cl. 257/94; 257/98; 257/E33.062

(57) ABSTRACT

It is an object of the present invention to provide a gallium nitride-based compound semiconductor light-emitting device which has a highly reflective positive electrode that has high reverse voltage and excellent reliability with low contact resistance to the p-type gallium nitride-based compound semiconductor layer.

The inventive reflective positive electrode for a semiconductor light-emitting device comprises a contact metal layer adjoining a p-type semiconductor layer, and a reflective layer on the contact metal layer, wherein the contact metal layer is formed of a platinum group metal or an alloy containing a platinum group metal, and the reflective layer is formed of at least one metal selected from the group consisting of Ag, Al, and alloys containing at least one of Ag and Al.

### CROSS REFERENCE TO RELATED APPLICATION

This application is an application filed under 35 U.S.C. §111(a) claiming benefit, pursuant to 35 U.S.C. §119(e) (1), of the filing date of the Provisional Application No.60/584,175 filed on Jul. 1, 2004, pursuant to 35 U.S.C. §111(b).

### TECHNICAL FIELD

The present invention relates to a reflective positive electrode for a light-emitting device and, more particularly, to a reflective positive electrode having excellent characteristics and stability, and to a flip chip type gallium nitride-based compound semiconductor light-emitting device using the same.

### BACKGROUND ART

In recent years, a gallium nitride-based compound semiconductor represented by the formula AlₓIn_{y}Ga_{1-x-y}N (0≦x<1, 0≦y<1, x+y<1) has attracted much attention as a material for a light-emitting diode (LED) emitting ultraviolet to blue light, or green light. Light emission of high intensity in the ultraviolet, blue and green regions, which was hitherto difficult, has been made possible by using a semiconductor made of these materials. Gallium nitride-based compound semiconductors are generally grown on a sapphire substrate. As this is an insulating substrate, unlike GaAs-based light-emitting devices, an electrode cannot be provided on rear surface of the substrate. Therefore, both negative and positive electrodes must be provided on the semiconductor grown as a crystal.

In particular, in the case of a-semiconductor device using a gallium nitride-based compound semiconductor, as the sapphire substrate is light-transmissive at the wavelength of emitted light, a flip chip type structure, in which the device is mounted with the electrode surface as the underside and light is extracted from the side of the sapphire substrate, has attracted much attention.

FIG. 1 is a schematic view showing an example of general structure of light-emitting device of this type. Thus, a light-emitting device has a buffer layer 2, a n-type semiconductor layer 3, a light-emitting layer 4, and a p-type semiconductor layer 5 successively grown as crystal on a substrate 1, with a portion of the light-emitting layer 4 and the p-type semiconductor layer 5 removed by etching so as to expose the n-type semiconductor layer 3, and a positive electrode 10 is formed on the p-type semiconductor layer 5 and a negative electrode 20 is formed on the n-type semiconductor layer 3. Such a light-emitting device is mounted, for example, with the surface having an electrode formed thereon facing to a lead frame, and then is bonded. Light emitted from the light-emitting layer 4 is extracted from the side of the substrate 1. In order to extract light efficiently in this type of light-emitting device, a reflective metal is used as the positive electrode 10, and is provided so as to cover the major portion of the p-type semiconductor layer 5 to thereby cause the light from the light-emitting layer toward the positive electrode to be reflected by the positive electrode 10 and to be extracted from the side of the substrate 1.

Therefore, low contact resistance and high reflectance are the properties required for the materials of positive electrode. Ag and Al are generally known as highly reflective metal, and an Ag layer of 20 nm or greater in thickness directly provided on the p-type semiconductor layer has been proposed as a reflective positive electrode (see Japanese Patent Application Laid-Open (kokai) No. 11-186599). As means for using Ag, Patent Document 1 proposes that a silver layer is provided on the p-type nitride semiconductor layer and a stabilizing layer is added on the silver layer. It is disclosed that the role of the stabilizing layer is to improve the mechanical and electrical properties of the silver layer.

However, when Ag and Al diffuse excessively into the p-type semiconductor layer, small current leaks occur, leading to lowering of the reverse voltage. This results, in a long-term aging test, in variation in characteristic values, and leads to a reduction in reliability. The reason for this seems to be that the crystallinity of the p-type semiconductor layer is deteriorated by diffusion of Ag and Al into the p-type semiconductor layer.

Further, a flip chip type light-emitting device has been proposed in which a metal thin film is provided on the p-type semiconductor layer in order to overcome non-uniformity of contact resistance (see Japanese Patent Application Laid-Open (kokai) No. 11-220168).

### DISCLOSURE OF INVENTION

It is an object of the present invention to provide a gallium nitride-based compound semiconductor light-emitting device which resolves the above-described problem associated with Ag and Al, namely, which has a highly reflective positive electrode that has high reverse voltage and excellent reliability with low contact resistance to the p-type gallium nitride-based compound semiconductor layer.

The present invention provides the following.

(1) A reflective positive electrode for a semiconductor light-emitting device comprising a contact metal layer adjoining a p-type semiconductor layer, and a reflective layer on the contact metal layer, wherein the contact metal layer is formed of a platinum group metal or an alloy containing a platinum group metal, and the reflective layer is formed of at least one metal selected from the group consisting of Ag, Al, and alloys containing at least one of Ag and Al.

(2) A reflective positive electrode for a semiconductor light-emitting device according to (1) above, wherein the contact metal layer is formed of Pt or an alloy thereof.

(3) A reflective positive electrode for a semiconductor light-emitting device according to (1) or

(2) above, wherein thickness of the contact metal layer is in the range of 0.1˜30 nm.

(4) A reflective positive electrode for a semiconductor light-emitting device according to (3) above, wherein thickness of the contact metal layer is in the range of 1˜30 nm.

(5) A reflective positive electrode for a semiconductor light-emitting device according to (3) above, wherein thickness of the contact metal layer is in the range of 0.1˜4.9 nm.

(6) A reflective positive electrode for a semiconductor light-emitting device according to any one of (1)˜(5) above, wherein a semiconductor-metal-containing layer containing a group III metal is present on the surface of the contact metal layer on the side of the p-type semiconductor layer.

(7) A reflective positive electrode for a semiconductor light-emitting device according to any one of (1)˜(6) above, wherein the contact metal layer is formed by an RF discharge sputtering method.

(8) A reflective positive electrode for a semiconductor light-emitting device according to any one of (1)˜(7) above, wherein the reflective layer is Ag or an alloy thereof.

(9) A reflective positive electrode for a semiconductor light-emitting device according to any one of (1)˜(8) above, wherein thickness of the reflective layer is 30˜500 nm.

(10) A reflective positive electrode for a semiconductor light-emitting device according to any one of (1)˜(9) above, wherein the reflective layer is formed by a DC discharge sputtering method.

(11) A reflective positive electrode for a semiconductor light-emitting device according to any one of (1)˜(10) above, wherein the device further comprises an overcoat layer that covers the contact metal layer and the reflective layer.

(12) A reflective positive electrode for a semiconductor light-emitting device according to (11) above, wherein thickness of the overcoat layer is at least 10 nm.

(13) A reflective positive electrode for a semiconductor light-emitting device according to (11) or

(12) above, wherein at least a part of the portion of the overcoat layer adjoining the upper surface of the reflective layer is metal.

(14) A reflective positive electrode for a semiconductor light-emitting device according to (13) above, wherein the overcoat layer is at least one metal selected from the group consisting of Ti, V, Cr, Mn, Fe, Co, Ni, Zr, Nb, Mo, Tc, Ru, Rh, Pd, Hf, Ta, W, Re, Os, Ir, Pt, Au and alloys containing any of these metals.

(15) A reflective positive electrode for a semiconductor light-emitting device according to (14) above, wherein the overcoat layer is at least one metal selected from the group consisting of Ru, Rh, Pd, Os, Ir, Pt, Au and alloys containing any of these metals.

(16) A reflective positive electrode for a semiconductor light-emitting device according to any one of (11)˜(15) above, wherein the overcoat layer is in ohmic contact with the p-type semiconductor layer.

(17) A reflective positive electrode for a semiconductor light-emitting device according to (16) above, wherein the overcoat layer is in ohmic contact with the p-type semiconductor layer at a contact resistivity of 1×10⁻³ Ωcm² or less.

(18) A reflective positive electrode for a semiconductor light-emitting device according to any one of (1)˜(17) above, wherein, after forming the contact metal layer, heat treatment is not performed at a temperature higher than 350° C.

(19) A gallium nitride-based compound semiconductor light-emitting device comprising a substrate; an n-type layer, a light-emitting layer, and a p-type layer, the layers being provided atop the substrate in this order and being formed of a Group III nitride semiconductor; a negative electrode provided on the n-type layer; and a positive electrode provided on the p-type layer, wherein the positive electrode is a positive electrode according to any one of (1)·(18) above.

(20) A gallium nitride-based compound semiconductor light-emitting device according to (19) above, wherein, on the surface of the p-type semiconductor layer on the side of the positive electrode, there exists a positive-electrode-metal-containing layer.

(21) A lamp comprising the gallium nitride-based compound semiconductor light-emitting device according to (19) or (20) above.

A reflective positive electrode for a semiconductor light-emitting device according to the present invention has a positive electrode contact metal layer of a platinum group metal inter posed between a p-type semiconductor layer and a positive electrode reflective layer of Ag or Al, so that diffusion of metal constituting the reflective layer, Ag or Al, into the p-type semiconductor layer is restrained, and therefore, the light-emitting device has good electrical characteristics and high reliability.

Contact resistance can be further reduced by providing a semiconductor-metal-containing layer containing a group III metal constituting the semiconductor on the surface of the positive electrode contact metal layer on the side of the semiconductor.

A gallium nitride base compound semiconductor light-emitting device according to the present invention has the contact resistance between the positive electrode and the p-type semiconductor further reduced by providing a positive-electrode-metal-containing layer containing the metal constituting the contact metal layer on the surface of the p-type semiconductor layer on the side of the positive electrode.

By forming the contact metal layer of the positive electrode by sputtering method using RF discharge, the positive-electrode-metal-containing layer and the semiconductor-metal-containing layer can be formed without an annealing process, so that productivity can be improved.

Also, by providing an overcoat layer so as to cover the side and upper surfaces of the reflective layer, the stability of the light-emitting device can be further improved.

### BRIEF DESCRIPTION OF DRAWINGS

FIG. 1 is a schematic view showing general structure of a flip chip type compound semiconductor light-emitting device according to prior art.

FIG. 2 is a schematic view showing an example of a flip chip type gallium nitride-based compound semiconductor light-emitting device according to the present invention.

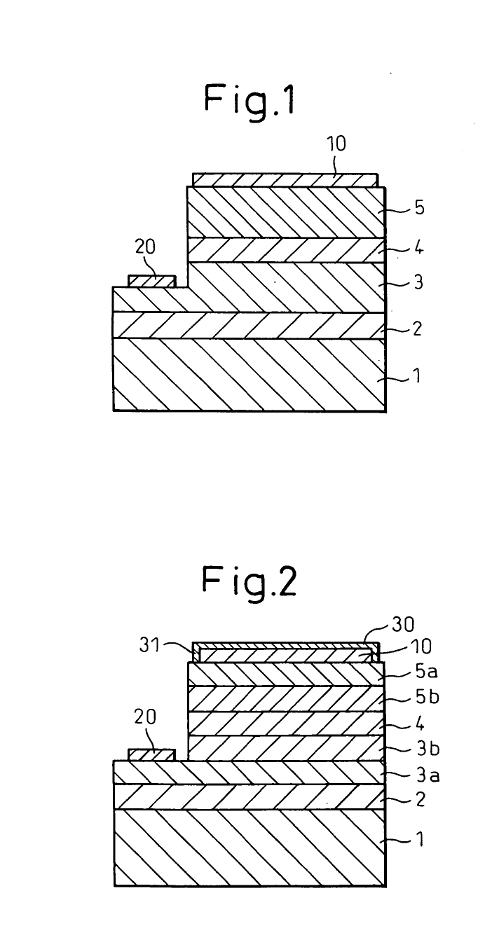

### BEST MODES FOR CARRYING OUT THE INVENTION

As a gallium nitride-based compound semiconductor laminated on the substrate in the present invention, one having a buffer layer 2, a n-type semiconductor layer 3, a light-emitting layer 4 and p-type semiconductor layer 5 grown on a substrate 1 can be used with no limitation. As the substrate, sapphire, SIC, and the like can be used with no limitation. As the gallium nitride-based semiconductor, various semiconductors represented by the formula AlₓIn_{y}Ga_{1-x-y}N (0≦x<1, 0≦y<1, x+y<1) are known. In the present invention, a gallium nitride-based compound semiconductor represented by the formula AlₓIn_{y}Ga_{1-x-y}N (0≦x<1, 0≦y<1, x+y<1) can be used with no limitation.

As an example, as shown in FIG. 2, a gallium nitride-based semiconductor laminate having a buffer layer 2 consisting of AlN layer, a n-contact layer 3a consisting of n-type GaN layer, a n-clad layer 3b consisting of n-type GaN layer, a light-emitting layer 4 consisting of InGaN layer, a p-clad layer 5b consisting of p-type AlGaN layer, and a p-contact layer 5a consisting of p-type GaN layer successively laminated on a sapphire substrate 1 in this order, can be used.

A part of the p-contact layer 5a, the p-clad layer 5b, the light-emitting layer 4 and the n-clad layer 3b of gallium nitride-based compound semiconductor is removed by etching, and a negative electrode 20 of, for example, Ti/Au is provided on the n-contact layer 3a, and a positive electrode 10 is provided on the p-contact layer 5a.

In the present invention, the positive electrode 10 has a contact metal layer adjoining the p-type semiconductor layer. A reflective layer is provided on the contact metal layer. The contact metal layer also serves as diffusion suppression layer to the reflective layer. Therefore, the contact metal layer is required to have a high light transmittance as well as a low contact resistance. Usually, a bonding pad layer is provided as the topmost layer for electrical connection to a circuit board or a lead frame.

As material for the contact metal layer, in order to achieve low contact resistance to the p-type semiconductor layer, it is preferable to use a metal having a high work function and, specifically, platinum group metals such as Pt, Ir, Rh, Pd, Ru and Os and alloys containing platinum group metals. Pt, Ir, Rh, and Ru are more preferable, and Pt is particularly preferable.

As the contact metal layer also has a role as a diffusion suppression layer for suppressing diffusion of Ag and Al constituting the reflective layer, it is preferable to use a metal of a dense structure and a high melting point. Specifically, a metal or an alloy with higher melting point than Ag and Al is preferable. From this standpoint also, platinum group metals are preferable as materials for the contact metal layer.

In order to stably achieve low contact resistance, the thickness of the contact metal layer is preferably 0.1 nm or greater, more preferably 1 nm or greater, particularly 2 nm or greater, and most preferably 3 nm or greater. In order to achieve uniform contact resistance, the thickness of the contact metal layer is preferably 1 nm or greater. In order to obtain sufficient light transmittance, thickness of the contact metal layer is preferably is preferably 30 nm or less, more preferably 20 nm or less, particularly 10 nm or less, and most preferably 4.9 nm or less. As the contact metal layer also has a role as diffusion suppression layer to Ag and Al, thickness is preferably 0.5 nm or greater from this viewpoint, more preferably 1 nm or greater. Preferably, the contact metal layer is a continuous layer.

Preferably, a semiconductor-metal-containing layer containing the metal constituting the semiconductor is present on the surface of the positive electrode contact metal layer on the side of the semiconductor, as this would further decrease the contact resistance. Thus, in the present invention, a “semiconductor-metal-containing layer” is defined as the semiconductor constituting metal containing layer in the contact metal layer.

Preferably, the thickness of the semiconductor-metal-containing layer is 0.1 - 3 nm. If thickness is less than 0.1 nm, an effect on the decrease of contact resistance is not significant, and if thickness exceeds 3 nm, light transmittance is lowered undesirably. More preferably, the thickness is 1-3 nm.

Preferably, a proportion of the semiconductor constituting metal contained in the layer is 0.1˜50 atom % relative to the total amount of metal. If this proportion is less than 0.1%, an effect on a decrease of contact resistance is not significant. If this proportion is more than 50 atom %, light transmittance may be lowered. More preferably, this proportion is 1˜20 atom %.

The thickness of the semiconductor-metal-containing layer and proportion of the semiconductor constituting metal contained in the layer can be measured by the EDS analysis of sectional TEM, as is well known to those skilled in the art. Thus, EDS analysis of a sectional TEM can be performed at several points, for example five points, in thickness direction from the lower surface of the contact metal layer (p-type semiconductor layer surface), and type and content of metal contained at each point can be determined from each chart at these points. If five measurement points are insufficient to determine the thickness, measurement can be made at several additional points.

Also, a positive-electrode-metal-containing layer, containing the metal constituting the contact metal layer, is preferably present on the surface of the p-type semiconductor layer on the side of the positive electrode. With such construction, contact resistance between the positive electrode and the p-type semiconductor layer can be further decreased.

In short, a “positive-electrode-metal-containing layer”, as used herein, is defined as a layer containing the metal constituting the contact metal layer, in the p-type semiconductor layer.

Preferably, the thickness of the positive-electrode-metal-containing layer is in the range of 0.1˜10 nm. If the thickness is less than 0.1 nm or more than 10 nm, it is difficult to achieve low contact resistance. The thickness is more preferably in the range of 1˜8 nm in order to achieve a better contact resistance.

The proportion of the contact metal layer constituting metal in the layer is preferably 0.01˜30 atom % relative to the total amount of metal. If this proportion is less than 0.01 atom %, it is difficult to achieve low contact resistance, and if this proportion is more than 30 atom %, the crystallinity of the semiconductor may be degraded. More preferably, the proportion is 1˜20 atom %. The layer may contain the reflective layer constituting metal. In such a case, the proportion of the reflective layer constituting metal, Ag or Al, is preferably 5 atom % or less relative to the total amount of metal. If this proportion is more than 5 atom %, a low current leakage component may be increased and a reverse voltage value may be lowered.

The thickness of the positive-electrode-metal-containing layer and content of the positive electrode constituting metal in this layer can be measured, as in the case of semiconductor-metal-containing layer, by using EDS analysis of a sectional TEM.

The reflective layer can be formed by using a metal having high reflectance, specifically Ag or Al, or an alloy containing at least one of these metals. Thickness of the reflective layer is preferably 30 nm or more. If thickness of the reflective layer is less than 30 nm, it is difficult to achieve uniform high reflectance all over the electrode. More preferably, the thickness is 50 nm or more. In view of production cost, thickness is preferably 500 nm or less.

The contact metal layer and the reflective layer may be formed by using any method well known to those skilled in the art, such as a sputtering method or a vacuum deposition method. The sputtering method is particularly preferable since it provides a contact metal layer having low contact resistance or a reflective layer having excellent reflectivity.

Preferably, a sputtering film forming method, using RF discharge, is used for forming the contact metal layer on the p-type semiconductor layer. By using a sputtering film forming method using RF discharge, an electrode with lower contact resistance can be obtained as compared to a vapor deposition method or a sputtering film forming method using DC discharge. Thus, when the contact metal layer is formed by a sputtering film forming method using RF discharge, the semiconductor-metal-containing layer and the positive-electrode-metal-containing layer can be simultaneously formed.

In a sputtering film forming method using RF discharge, it is conjectured that energy can be imparted to the sputtered atom attached to the p-type semiconductor layer by ion assist effect, and diffusion of the sputtered atom in the surface portion of p-type semiconductor layer, for example, Mg doped p-GaN, may be promoted. Further, it is conjectured that, in above film forming, energy may be imparted to the topmost atom of the p-type semiconductor layer, and diffusion of the material for the semiconductor, for example Ga, into the contact metal layer may be promoted. In EDS analysis of a sectional TEM, in the contact metal layer that is film formed by RF sputtering on p-type GaN, a region in which both Ga derived from the semiconductor and Pt as the material of the contact metal layer could be detected, that is, a semiconductor-metal-containing layer, was confirmed. In this analysis, presence of N in this region could not be confirmed.

On the other hand, on the semiconductor side, a region in which Ga, N and Pt could be all detected, that is, a positive-electrode-metal-containing layer, was confirmed.

In the film formation using RF discharge, contact resistance is lowered initially, but as the film thickness increases, as the film is not dense, the reflectance of the formed film becomes inferior to the film formed by DC discharge. Therefore, preferably, the contact metal layer is formed by RF discharge as a thin film in the range that permits contact resistance to be maintained low and light transmittance to be raised, and the reflective layer is formed thereon by DC discharge.

As has been described above, by forming the contact metal layer by RF sputtering, the semiconductor-metal-containing layer and the positive-electrode-metal-containing layer according to the present invention can be formed. In this case, annealing after formation of the contact metal layer is not required. Rather, annealing would promote diffusion of both Pt and Ga, and crystallinity of the semiconductor may be degraded and electrical characteristics may be deteriorated. After formation of the contact metal layer, heat treatment at temperature higher than 350° C. is preferably not performed.

The metal derived from the material of the positive ) 25 electrode and the metal such as Ga and N derived from the semiconductor in the semiconductor-metal-containing layer and the positive-electrode-metal-containing layer may be present as compounds or alloys, or may be present as simple mixtures. In any case, low resistance can be obtained by eliminating the interface between the contact metal layer and the p-type semiconductor layer.

Sputtering may be carried out using any known conventional sputtering apparatus under any suitably selected conditions conventionally known. A substrate having gallium nitride-based compound semiconductor layers laminated thereon is placed in the chamber, and temperature of the substrate is set in the range from room temperature to 500° C. Although heating of the substrate is not particularly required, the substrate may be suitably heated in order to promote diffusion of the metal constituting the contact metal layer and the metal constituting the semiconductor layer. The chamber is evacuated to the degree of vacuum in the range of 10⁻⁴˜10⁻⁷ Pa. He, Ne, Ar, Kr, Xe, etc. can be used as the sputtering gas. Ar is preferred in view of availability. One of these gases is introduced into the chamber up to the pressure of 0.1˜10 Pa, and then, discharge is performed. Preferably the pressure is in the range of 0.2˜5 Pa. Supplied electric power is preferably in the range of 0.2˜2.0 kW. By suitably adjusting the discharge time and supplied power, the thickness of the formed layer can be adjusted. The content of oxygen in the required target used for sputtering is preferably 10000 ppm or less in order to reduce the oxygen content of the formed layer, and is more preferably 6000 ppm or less.

As the bonding pad layer, various structures using materials such as Au, Al, Ni and Cu are well known, and these well known materials and structures can be used with no restriction. Preferably, the thickness is in the range of 100˜1000 nm. The thickness is more preferably 300 nm or more since higher bondability is obtained with thick bonding pad owing to the property of bonding pads. However, from the viewpoint of production cost, the thickness is preferably 500 nm or less.

With Ag and Al and the like, a phenomenon called electromigration is generally known in which these metals are ionized and diffuse in the presence of water. With an electrode using Ag or Al, in an atmosphere in which water is present in the surroundings, precipitates having Ag or Al as a main component are produced by electric current application. When the precipitates produced in the positive electrode reach the negative electrode, electric current applied to the device ceases to flow through the light-emitting layer, and light is no longer emitted by the device. Light is also not emitted by the device when the p-type semiconductor and the n-type semiconductor are connected by the precipitates.

In order to avoid this, an overcoat layer is preferably provided so as to cover the side and upper surface of the reflective layer. The overcoat layer has the role of preventing Ag or Al in the reflective layer from coming into contact with moisture in the air.

The material for the overcoat layer may be any material such as metals, inorganic oxides, inorganic nitrides, resins, etc., as long as a thin film can be formed so as to cover the side and upper surface of the contact metal layer and the reflective layer. However, it must be an electro-conductive metal at least in the portion of the upper surface of the reflective layer where the bonding pad layer is formed.

Thus, it is desirable that material for-the overcoat layer is at least one metal selected from the group consisting of Ti, V, Cr, Mn, Fe, Co, Ni, Zr, Nb, Mo, Tc, Ru, Rh, Pd, Hf, Ta, W, Re, Os, Ir, Pt, Au, or an alloy containing at least one of these metals. Corrosive metals (alkali metals, alkali earth metals) and low melting point metals (400° C. or lower) are undesirable. Au, that is suitable as material for the bonding pad layer, may be used for overcoat layer so that the overcoat layer can also serve as the bonding pad layer.

It is desirable that the overcoat layer is, at its side portion, in ohmic contact with the p-type semiconductor. Due to this ohmic contact, the light-emitting layer emits light in the region corresponding to the portion directly under the side of the overcoat layer. In the device as a whole, the forward voltage can be lowered. A platinum group metal such as Ru, Rh, Pd, Os, Ir, and Pt or an alloy containing at least one platinum group metal is preferred since ohmic contact can be easily obtained. Contact resistivity value of 1×10⁻³ Ωcm² or less is desirable. The value of contact resistivity is measured using TLM method.

Thickness of the overcoat layer is preferably 10 nm or more because the layer needs to separate the reflective layer from moisture in the external air. There is no particular upper bound, but in view of production cost, thickness is preferably 200 nm or less. In the above-described case where the overcoat layer serves also as the bonding pad layer, needless to say, it must have required thickness as the bonding pad layer. Preferably, thickness of the side portion is as thick as 1˜50 μm, more preferably 5˜40 μm, because, as described above, light-emitting area of the light-emitting layer is increased and forward voltage is lowered.

The overcoat layer should not have structure such as fine tubular hole that permits water to easily permeate in it.

Well known methods for forming thin films such as sputtering, vacuum deposition, solution coating method, etc., can be used with no particular limitation for forming the overcoat layer. In case of above-described metals, in particular, sputtering or vacuum deposition methods are preferably used for forming the overcoat layer.

### EXAMPLES

The present invention will now be described in more detail below with reference to Examples and Comparative example. It is to be understood that the present invention is by no means limited by these Examples.

The materials for the contact metal layer, reflective layer, overcoat layer and bonding pad layer used in the Examples and Comparative example, and characteristics of the device obtained are shown in Table 1. Each of the characteristics is the value measured at electric current of 20 mA.

### Example 1

FIG. 2 is a schematic view showing a gallium nitride-based compound semiconductor light-emitting device fabricated in the present Example.

The gallium nitride-based compound semiconductor was formed by laminating a buffer layer 2 of ALN layer on a sapphire substrate 1, and by successively laminating thereon a n-contact layer 3a of n-type GaN layer, a n-clad layer 3b of n-type GaN layer, a light-emitting layer 4 of InGaN layer, a p-clad layer 5b of p-type AlGaN layer, a p-contact layer 5a of p-type GaN layer. The n-contact layer 3a is n-type GaN layer doped with Si at 7×10¹⁸/cm³, and n-clad layer 3b is n-type GaN layer doped with Si at 5×10¹⁸/cm³. The light-emitting layer 4 has single quantum well structure, and the composition of InGaN is In_{0.95}Ga_{0.05}N. The p-clad layer 5b is p-type AlGaN doped with Mg at 1×10¹⁸/cm³, and the composition is Al_{0.25}Ga_{0.75}N. The p-contact layer 5a is p-type GaN layer doped with Mg at 5×10¹⁹/cm³. Lamination of these layers were carried out by MOCVD method under the usual conditions well known to those skilled in the art.

A flip-chip type gallium nitride-based compound semiconductor light-emitting device was fabricated by providing a positive electrode 10 and negative electrode 20 to this gallium nitride-based compound semiconductor laminate following the procedure as described below.

(1) First, the n-contact layer 3a of the negative electrode forming region was exposed in the above-described gallium nitride-based compound semiconductor laminate. The procedure is as follows. Using known lithographic technology and lift-off technology, an etching mask was formed on the region other than the negative electrode forming region on the p-contact layer 5a.

Then, after etching was performed by reactive ion dry etching method until the n-contact layer 3a was exposed, the laminate was taken out from the etching apparatus, and the etching mask was removed by washing with acetone.

(2) Then, a positive electrode 10 was formed as follows. After the device was treated in boiling concentrated HCl for 10 minutes in order to remove an oxide film on the surface of the p-contact layer 5a, a positive electrode was formed on the p-contact layer 5a. First, a contact metal layer and reflective layer were formed. The procedure for forming these layers is as follows.

A resist is coated uniformly, and known lithographic technique was used to remove the resist from a positive electrode forming region. After immersing the device in buffered hydrofluoric acid (BHF) at room temperature for one minute, a contact metal layer and a reflective layer were formed in a vacuum sputtering apparatus. Operating conditions for forming these layers by sputtering method are as follows.

A chamber was evacuated until the degree of vacuum was 10⁻⁴ Pa or lower, and above-described gallium nitride-based compound semiconductor was placed in the chamber, and Ar gas was introduced into the chamber as sputtering gas and RF discharge was performed at 3 Pa to form a contact metal layer. The electric power supplied was 0.5 kW, and Pt film was formed as the contact metal layer in film thickness of 4.0 nm.

Then, under the above pressure and supplied power, an Ag reflective layer was formed in thickness of 200 nm by sputtering with DC discharge. After the laminate was taken out from the sputtering apparatus, using lift-off technique, a metal film other than that at the positive electrode forming region was removed together with the resist.

Next, an overcoat layer 30 was formed. After a resist was coated uniformly, a known lithographic technique was used to open an overcoat region as a window somewhat larger than the positive electrode region. The size of the window was such that the thickness of the side portion 31 of the overcoat layer was 10 μm. Sputtering with DC discharge was used to form an Au film of 400 nm in thickness. After taking out the device from the sputtering apparatus, a lift-off technique was used to remove a metal film together with the resist other than that on the overcoat layer region. This overcoat layer 30 also serves as a bonding pad layer.

(3) A negative electrode 20 was formed on the n-contact layer 3a. The procedure for forming the negative electrode 20 is as follows. After a resist was coated uniformly all over the surface, on the region exposed up to n-contact layer 3a, a known lithographic technique was used to open a window for negative electrode region, and vapor deposition method was used to deposit Ti and Au films in thickness of 100 nm and 300 nm, respectively. Metal films other than that on the negative electrode region were removed together with the resist.

(4) Then, a protective film was formed. The procedure is as follows. After a resist was coated uniformly all over the surface, a known lithographic technique was used to open a window on a portion between the positive electrode and the negative electrode, and SiO₂ film was formed in thickness of 200 nm by sputtering method using RF discharge. SiO₂ film other than that on the protective film region was removed together with the resist.

(5) The wafer was cut into pieces, to thereby fabricate pieces of the gallium nitride-based compound semiconductor light-emitting device of the present invention.

The gallium nitride-based compound semiconductor light-emitting device obtained was mounted on a TO-18, and device characteristics were measured at an applied current of 20 mA. The result is shown in Table 1. An aging test was conducted at room temperature and a relative humidity of about 50% on a TO-18 at an applied current of 30 mA for 100 hours.

As a result of EDS analysis of a sectional TEM, it was found that thickness of the semiconductor-metal-containing layer was 2.5 nm, and proportion of Ga relative to total metal (Pt+Ag+Ga) was estimated to be 1˜20 atom % in the layer. Thickness of the positive-electrode-metal-containing layer in the p-contact layer was 6.0 nm. The positive electrode material present was Pt constituting the contact metal layer, and proportion relative to total metal (Pt+Ga) was estimated to be 1-10 atom % in the layer.

### Examples 2˜

A gallium nitride-based compound semiconductor light-emitting device was fabricated in the same manner as in Example 1, except that materials for reflective layer and overcoat layer were changed, and the characteristics of the device was evaluated as in Example 1. The result was shown together in Table 1. In Example 3 and 4 in which metals such as Pt and W other than Au were used as the overcoat layer, Au film of 400 nm in thickness was provided as the bonding pad layer on the overcoat layer 30. The side portion 31 of the Pt overcoat layer was in ohmic contact with p-contact layer 5a, and the contact resistivity as determined by TLM method was 5×10⁻⁴ Ωcm². Example 5 is the same as Example 1 except that thickness of side portion 31 of the overcoat layer was 1 μm.

The positive-electrode-metal-containing layer of these light-emitting devices was 1˜8 nm in thickness, and proportion of the positive electrode metal was in the range of 0.5˜18 atom %. The semiconductor-metal-containing layer was 0.5˜3 nm in thickness, and proportion of Ga was in the range of 1˜20 atom %.

### Comparative Example

A device was fabricated in the same manner as in Example 1, except that the contact metal layer was not provided. Characteristics of this device was evaluated as in Example 1, and the result was shown together in Table 1. The forward voltage was higher, and the reverse voltage was lower.

### Examples 6˜8)

A gallium nitride-based compound semiconductor light-emitting device was fabricated in Example 1, varying only the thickness of the contact metal layer, and the characteristics of the device was evaluated as in Example 1. Result was shown together in Table 1.

Thickness of the positive-electrode-metal-containing layer was in the range of 1˜8 nm, and the proportion of the positive electrode metal was in the range of 0.5˜18 atom %. Thickness of the semiconductor-metal-containing layer was in the range of 0.5˜3 nm, and the proportion of Ga was in the range of 1˜20 atom %.

TABLE 1

| | Contact metal layer | | | | | Device characteristics | | |
|---|---|---|---|---|---|---|---|---|
| | | Film | | | | (after 100 hours of aging) | | |
| | | thickness | Reflective | Overcoat | Bonding | Forward | Reverse | Output |
| | material | (nm) | layer | layer | pad layer | voltage (V) | voltage (V) | power (mW) |
| Example 1 | Pt | 2 | Ag | Au | — | 3.3 | >20 | 6.5 |
| Example 2 | Pt | 2 | Al | Au | — | 3.3 | >20 | 6.3 |
| Example 3 | Pt | 2 | Al | Pt | Au | 3.3 | >20 | 6.5 |
| Example 4 | Pt | 2 | Ag | W | Au | 3.3 | >20 | 6.5 |
| Example 5 | Pt | 2 | Ag | Au | — | 3.4 | >20 | 6.5 |
| Example 6 | Pt | 1 | Ag | Au | — | 3.6 | >20 | 6.7 |
| Example 7 | Pt | 0.5 | Ag | Au | — | 4 | >20 | 6.9 |
| Example 8 | Pt | 5 | Ag | Au | — | 3.3 | >20 | 6 |
| Comparative | no contact | 0 | Ag | Au | — | 3.6 | 5 | 6.6 |
| example | metal | | | | | | | |

### Examples 9˜11

A gallium nitride-based compound semiconductor light-emitting device was fabricated in the same manner as in Example 1, except that heat treatment was conducted after forming Ag reflective layer, and characteristics of the device was evaluated as in Example 1. Heat treatment was conducted in a RTA furnace in air by varying the temperature for 10 minutes. Table 2 shows temperature of heat treatment and forward voltage. Forward voltage was somewhat higher in the light-emitting device subjected to heat treatment at 400° C.

TABLE 2

| | Heating temperature | Forward voltage |
|---|---|---|
| | (° C.) | (V) |
| Example 1 | — | 3.3 |
| Example 9 | 200 | 3.3 |
| Example 10 | 300 | 3.3 |
| Example 11 | 400 | 3.8 |

### INDUSTRIAL APPLICABILITY

The gallium nitride-based compound semiconductor light-emitting device provided by the present invention has excellent characteristics and stability, and is useful as a material for a light-emitting diode, a lamp, etc.

1. A reflective positive electrode for a semiconductor light-emitting device comprising a contact metal layer adjoining a p-type semiconductor layer, and a reflective layer on the contact metal layer, wherein the contact metal layer is formed of a platinum group metal or an alloy containing a platinum group metal, and the reflective layer is formed of at least one metal selected from the group consisting of Ag, Al, and alloys containing at least one of Ag and Al.

2. A reflective positive electrode for a semiconductor light-emitting device according to claim 1, wherein the contact metal layer is formed of Pt or an alloy thereof.

3. A reflective positive electrode for a semiconductor light-emitting device according to claim 1, wherein thickness of the contact metal layer is in the range of 0.1˜30 mn.

4. A reflective positive electrode for a semiconductor light-emitting device according to claim 3, wherein thickness of the contact metal layer is in the range of 1˜30 nm.

5. A reflective positive electrode for a semiconductor light-emitting device according to claim 3, wherein thickness of the contact metal layer is in the range of 0.1˜4.9 nm.

6. A reflective positive electrode for a semiconductor light-emitting device according to claim 1, wherein a semiconductor-metal-containing layer containing a group III metal is present on the surface of the contact metal layer on the side of the p-type semiconductor layer.

7. A reflective positive electrode for a semiconductor light-emitting device according to claim 1, wherein the contact metal layer is formed by an RF discharge sputtering method.

8. A reflective positive electrode for a semiconductor light-emitting device according to claim 1, wherein the reflective layer is Ag or an alloy thereof.

9. A reflective positive electrode for a semiconductor light-emitting device according to claim 1, wherein thickness of the reflective layer is 30˜500 nm.

10. A reflective positive electrode for a semiconductor light-emitting device according to claim 1, wherein the reflective layer is formed by a DC discharge sputtering method.

11. A reflective positive electrode for a semiconductor light-emitting device according to claim 1, wherein the device further comprises an overcoat layer that covers the contact metal layer and the reflective layer.

12. A reflective positive electrode for a semiconductor light-emitting device according to claim 11, wherein thickness of the overcoat layer is at least 10 nm.

13. A reflective positive electrode for a semiconductor light-emitting device according to claim 11, wherein at least a part of the portion of the overcoat layer adjoining the upper surface of the reflective layer is metal.

14. A reflective positive electrode for a semiconductor light-emitting device according to claim 13, wherein the overcoat layer is at least one metal selected from the group consisting of Ti, V, Cr, Mn, Fe, Co, Ni, Zr, Nb, Mo, Tc, Ru, Rh, Pd, Hf. Ta, W, Re, Os, Ir, Pt, Au and alloys containing any of these metals.

15. A reflective positive electrode for a semiconductor light-emitting device according to claim 14, wherein the overcoat layer is at least one metal selected from the group consisting of Ru, Rh, Pd, Os, Ir, Pt, Au and alloys containing any of these metals.

16. A reflective positive electrode for a semiconductor light-emitting device according to claim 11, wherein the overcoat layer is in ohmic contact with the p-type semiconductor layer.

17. A reflective positive electrode for a semiconductor light-emitting device according to claim 16, wherein the overcoat layer is in ohmic contact with the p-type semiconductor layer at a contact resistivity of 1×10⁻³ Ωcm² or less.

18. A reflective positive electrode for a semiconductor light-emitting device according to claim 1, wherein, after forming the contact metal layer, heat treatment is not performed at a temperature higher than 350° C.

19. A gallium nitride-based compound semiconductor light-emitting device comprising a substrate; an n-type layer, a light-emitting layer, and a p-type layer, the layers being provided atop the substrate in this order and being formed of a Group III nitride semiconductor; a negative electrode provided on the n-type layer; and a positive electrode provided on the p-type layer, wherein the positive electrode is a positive electrode according to claim 1.

20. A gallium nitride-based compound semiconductor light-emitting device according to claim 19, wherein, on the surface of the p-type semiconductor layer on the side of the positive electrode, there exists a positive-electrode-metal-containing layer.

21. A lamp comprising the gallium nitride-based compound semiconductor light-emitting device according to claim 19.
